(19) United States
(12) Patent Application Publication
(10) Pub. No.: US 2017/0160608 A1
(43) Pub. Date: Jun. 8, 2017

(54) TFT Display Device And The Method For Producing The Same

(71) Applicant: Shenzhen China Star Optoelectronics Technology Co., Ltd., Shenzhen, Guangdong (CN)

(72) Inventors: Kecheng XIE, Shenzhen, Guangdong (CN); Ri HONG, Shenzhen, Guangdong (CN)

(73) Assignee: Shenzhen China Star Optoelectronics Technology Co., Ltd., Shenzhen, Guangdong (CN)

(21) Appl. No.: 14/895,433

(22) PCT Filed: May 18, 2015
(86) PCT No.: PCT/CN2015/079175

§ 371 Date: Dec. 2, 2015

(30) Foreign Application Priority Data
May 6, 2015 (CN) 201510227667.X

(51) Int. Cl. G02F 1/1362; G02F 1/1368; H01L 27/12

(52) U.S. Cl. CPC G02F 1/136204; H01L 27/124; H01L 27/1262; G02F 1/1368; G02F 2201/503

(57) ABSTRACT

A TFT display device and a method for producing the device are disclosed. The TFT display device includes: a first metal layer, on which a first silicon nitride film is deposited; a second metal layer deposited on the first silicon nitride film and etched to form a pattern, wherein a second silicon nitride film is deposited on the second metal film; and a via hole, wherein the first metal layer and/or the second metal layer are disconnected in the overlapping region. The first silicon nitride layer and the second silicon nitride layer are etched to form the via hole On the disconnected position, and an ITO conductive film is deposited to electrically connect the disconnected position. According to the present invention, by means of the above-mentioned way, the TFT display device will have less damage by ESD. The yield rate of the product is increased, and the product competitiveness is enhanced.

### FIELD

The present invention relates to liquid crystal display field, more particularly to a TFT display device and a method for producing the same.

### BACKGROUND

The process for producing thin film transistor (TFT) display device is complicated, which needs many procedures to complete. Among them, many high temperature procedures, such as metal film forming, non-metal film forming, and dry etching procedures. These procedures should be conducted in high temperature environment. Thus, there is higher possibility that electro-static discharge (ESD) occurs. If the product design has poor protection to ESD, the TFT display device is easily punched through by ESD. Currently, there are many ESD protection ways to the TFT display device, and some are effective. Generally, ESD easily occurs in the overlapping region of upper and lower metal layers, as shown in FIGS. 1(a) and 1(b). When the upper and lower metal layers cross over and overlap, if the electrostatic current is too large, ESD punch through phenomenon occurs in the upper and lower overlapping region. General way is to decrease the metal line width in the overlapping region, in order to decrease damage of the metal lines by ESD.

### SUMMARY

The technical problem that the present invention mainly solves is to provide a TFT display device and a method for producing the device. The TFT display device will have less damage by ESD. The yield rate of the product is increased, and the product competitiveness is enhanced.

To solve the above-mentioned technical problem, according to the present invention, one technical way is to provide a TFT display device, comprising a first metal layer, wherein a first silicon nitride film is deposited on the first metal layer; a second metal layer deposited on the first silicon nitride film and etched to form a pattern, wherein a second silicon nitride film is deposited on the second metal film; a via hole, wherein in an overlapping region of the second metal layer and the first metal layer, the first metal layer and/or the second metal layer are disconnected, wherein on the disconnected position, the first silicon nitride layer and the second silicon nitride layer are etched to form the via hole, and an ITO conductive film is deposited to electrically connect the disconnected position. The via hole is passed through the first silicon nitride film and the second silicon nitride film, and is contacted with the first metal layer and/or the second metal layer. When the first metal layer is disconnected, the ITO conductive film on the via hole position is contacted with the first metal layer, such that the disconnected position of the first metal layer is electrically connected through the ITO conductive film.

The ITO conductive film is coated on the second silicon nitride film.

When the second metal layer is disconnected, the ITO conductive film on the via hole position is contacted with the second metal layer, such that the disconnected position of the second metal layer is electrically connected through the ITO conductive film.

To solve the above-mentioned technical problem, according to the present invention, another technical way is to provide a TFT display device, comprising a first metal layer, wherein a first silicon nitride film is deposited on the first metal layer; a second metal layer deposited on the first silicon nitride film and etched to form a pattern, wherein a second silicon nitride film is deposited on the second metal film; and a via hole, wherein in an overlapping region of the second metal layer and the first metal layer, the first metal layer and/or the second metal layer are disconnected, wherein on the disconnected position, the first silicon nitride layer and the second silicon nitride layer are etched to form the via hole, and an ITO conductive film is deposited to electrically connect the disconnected position.

The via hole is passed through the first silicon nitride film and the second silicon nitride film, and is contacted with the first metal layer and/or the second metal layer.

The ITO conductive film is coated on the second silicon nitride film.

When the first metal layer is disconnected, the ITO conductive film on the via hole position is contacted with the first metal layer, such that the disconnected position of the first metal layer is electrically connected through the ITO conductive film.

When the second metal layer is disconnected, the ITO conductive film on the via hole position is contacted with the second metal layer, such that the disconnected position of the second metal layer is electrically connected through the ITO conductive film.

To solve the above-mentioned technical problem, according to the present invention, another technical way is to provide a method for producing a TFT display device. The method comprises: depositing a first silicon nitride film on a first metal layer; depositing a second metal layer on the first silicon nitride film, etching the second metal layer to form a pattern, and depositing a second silicon nitride film on the second metal layer; in an overlapping region of the second metal layer and the first metal layer, disconnecting the first metal layer and/or the second metal layer, on the disconnected position, etching the first silicon nitride layer and the second silicon nitride layer to form a via hole, and depositing an ITO conductive film to electrically connect the disconnected position.

The via hole is passed through the first silicon nitride film and the second silicon nitride film, and is contacted with the first metal layer and/or the second metal layer.

The ITO conductive film is coated on the second silicon nitride film.

When the first metal layer is disconnected, the ITO conductive film on the via hole position is contacted with the first metal layer, such that the disconnected position of the first metal layer is electrically connected through the ITO conductive film.

When the second metal layer is disconnected, the ITO conductive film on the via hole position is contacted with the second metal layer, such that the disconnected position of the second metal layer is electrically connected through the ITO conductive film.

The following is the advantage of the present invention, compared to current technology. In the TFT display device of the present invention, a silicon nitride film is deposited on a first metal layer; a second metal layer is deposited on the first silicon nitride film and etched to form a pattern, wherein a second silicon nitride film is deposited on the second metal film; in an overlapping region of the second metal layer and the first metal layer, the first metal layer and/or the second metal layer are disconnected, wherein on the disconnected position, the first silicon nitride layer and the second silicon nitride layer are etched to form the via hole, and an ITO conductive film is deposited to electrically connect the disconnected position. By means of the TFT display device of the present invention, the TFT display device will have less damage by ESD. The yield rate of the product is increased, and the product competitiveness is enhanced.

### BRIEF DESCRIPTION OF THE DRAWINGS

FIG. 1 shows ESD punch through phenomenon of the TFT display device in conventional technology.

FIG. 2 is a cross-sectional view of the TFT display device according to the first embodiment of the present invention.

FIG. 3 is a plane view of the TFT display device of FIG. 2.

FIG. 4 is a cross-sectional view of the TFT display device according to the second embodiment of the present invention.

FIG. 5 is a plane view of the TFT display device of FIG. 4.

FIG. 6 is a flow chart showing the method for producing the TFT display device according to the embodiment of the present invention.

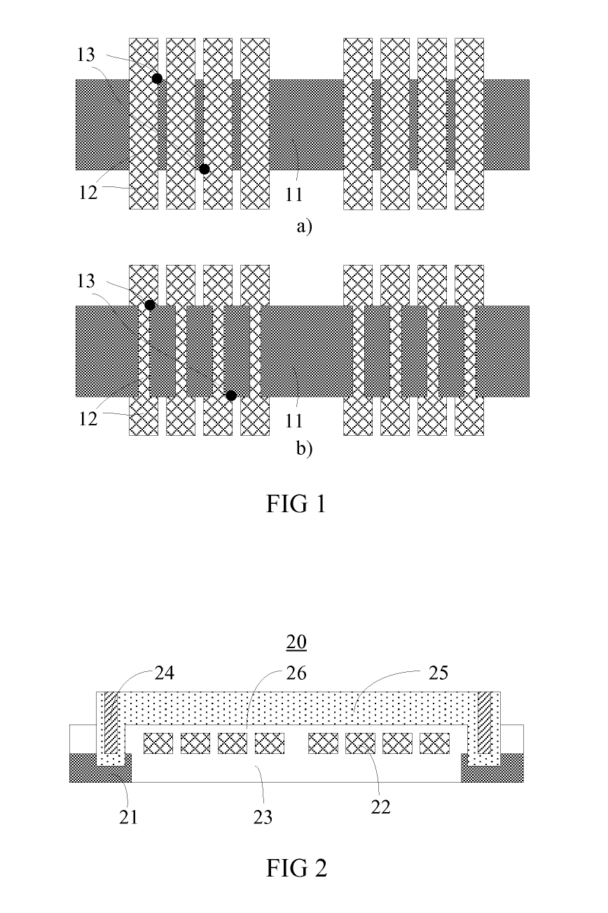

### DETAILED DESCRIPTION OF THE INVENTION

Please refer to FIG. 2, which shows a cross-sectional view of the TFT display device according to the first embodiment of the present invention. As shown in FIG. 2, the TFT display device 20 includes a first metal layer 21, a second metal layer 22, a first silicon nitride film 23, a via hole 24, an ITO conductive film 25, and a second silicon nitride film 26. The first silicon nitride film 23 is deposited on the first metal layer 21. The second metal layer 22 is deposited on the first silicon nitride film 23, and etched to form a pattern. The second silicon nitride film 26 is deposited on the second metal film 22. In the overlapping region of the second metal layer 22 and the first metal layer 21, the first metal layer 21 and/or the second metal layer 22 are disconnected. On the disconnected position, the first silicon nitride film 23 and the second silicon nitride film 26 are etched to form the via hole 24. The ITO conductive film 25 is deposited to electrically connect the disconnected position. Thus, in the peripheral region of the TFT display device, the metal trace with larger line width is replaced by the trace of ITO film. In addition, two ends of the metal trace is connected by the via hole bridging. ESD generated from the cross-over wire between the metal trace of larger line width and the metal trace of smaller line width can be decreased. ESD on the TFT display device can be dispersed and led away. Thus, the TFT display device will have less damage by ESD. The yield rate of the product is increased, and the product competitiveness is enhanced.

In the embodiment of the present invention, the ITO conductive film 25 is coated on the second silicon nitride film 26. The via hole 24 is passed through the first silicon nitride film 23 and the second silicon nitride film 26, and is contacted with the first metal layer 21 and/or the second metal layer 22. The first silicon nitride film 23 and the second silicon nitride film 26 can be the same silicon nitride film, such as SiNx film. In other embodiments of the present invention, different silicon nitride films can also be used.

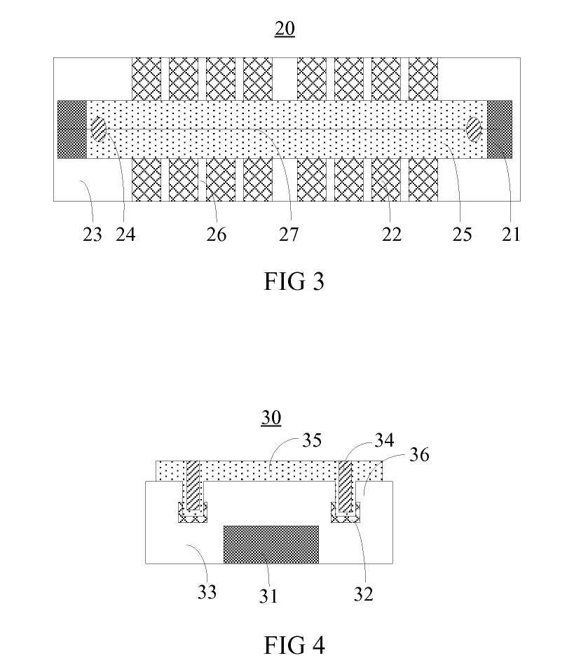

FIG. 2 is a cross-sectional view, showing that in the overlapping region of the second metal layer 22 and the first metal layer 21, the first metal layer 21 is disconnected. FIG. 3 is a corresponding plane view, and 27 is a cross line. The ITO conductive film 25 on the via hole 24 position is contacted with the first metal layer 21. Thus, the disconnected position of the first metal layer 21 is electrically connected through the ITO conductive film 25.

FIG. 4 is a cross-sectional view, showing that in the overlapping region of the second metal layer 32 and the first metal layer 31, the second metal layer 32 is disconnected. FIG. 5 is a corresponding plane view, and 37 is a cross line. The first silicon nitride layer 33 is deposited on the first metal layer 31, the second metal layer 32 is deposited on the first silicon nitride layer 33 and is etched to form a pattern. The second silicon nitride layer 36 is deposited on the second metal layer 32. On the disconnected position of the second metal layer 32, the first silicon nitride layer 33 and the second silicon nitride layer 36 are etched to form the via hole 34, and the ITO conductive film 35 is deposited on the second silicon nitride layer 36. In this way, on the via hole 34 position, the ITO conductive film 35 is contacted with the second metal layer 32, such that the disconnected position of the second metal layer 32 is electrically connected through the ITO conductive film 35. Thus, in the overlapping region of the second metal layer 32 and the first metal layer 31, by means of different conductivity of the via hole material, ESD on the TFT display device can be distributed and led away using capacitance difference between different material. Thus, the TFT display device will have less damage by ESD. The yield rate of the product is increased, and the product competitiveness is enhanced.

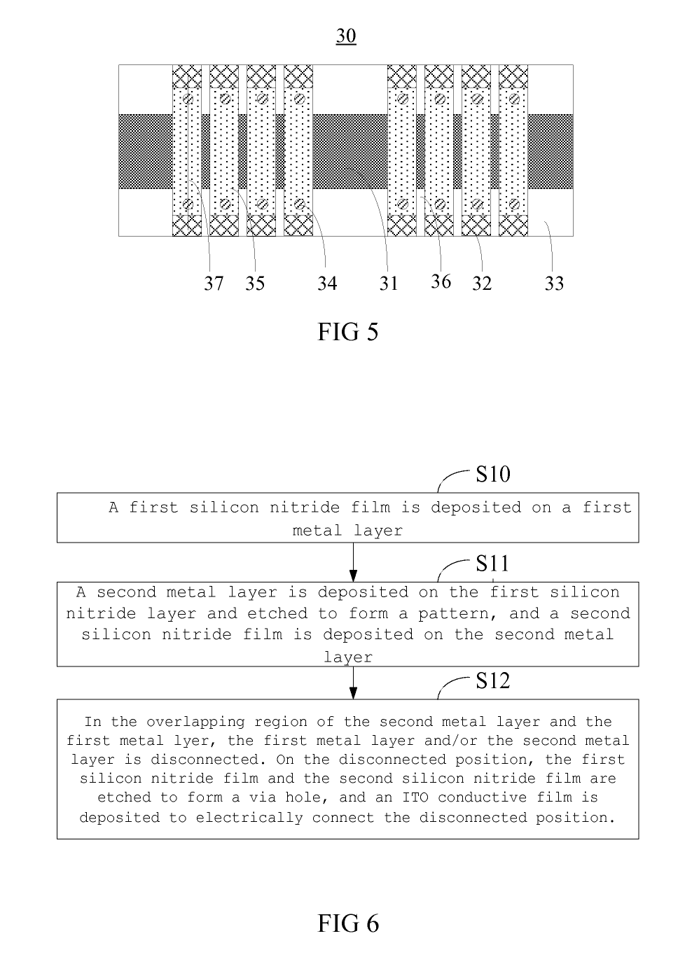

FIG. 6 is a flow chart showing the method for producing the TFT display device of the embodiment of the present invention. As shown in FIG. 6, the method for producing the TFT display device includes:

Step 10: A first silicon nitride film is deposited on a first metal layer.

Step 11: A second metal layer is deposited on the first silicon nitride layer and etched to form a pattern, and a second silicon nitride film is deposited on the second metal layer.

Step 12: In the overlapping region of the second metal layer and the first metal layer, the first metal layer and/or the second metal layer is disconnected. On the disconnected position, the first silicon nitride film and the second silicon nitride film are etched to form a via hole, and an ITO conductive film is deposited to electrically connect the disconnected position.

ITO conductive film is coated on the second silicon nitride film. The via hole is passed through the first silicon nitride film and the second silicon nitride film and is contacted with the first metal layer and/or the second metal layer. Specifically, in the overlapping region of the second metal layer and the first metal layer, when the first metal layer is disconnected, the ITO conductive film on the via hole position is contacted with the first metal layer, such that the disconnected position of the first metal layer is electrically connected through the ITO conductive film. In the overlapping region of the second metal layer and the first metal layer, when the second metal layer is disconnected, the ITO conductive film on the via hole position is contacted with the second metal layer, such that the disconnected position of the second metal layer is electrically connected through the ITO conductive film. Also, in other embodiments of the present invention, in the overlapping region of the second metal layer and the first metal layer, the first metal layer and the second metal layer can be both disconnected. Individually, the disconnected positions of the first metal layer and the second metal layers are electrically connected through different or the same ITO conductive film. Thus, in the peripheral region of the TFT display device, the metal trace with larger line width is replaced by the trace of ITO film. In addition, two ends of the metal trace is connected by the via hole bridging. ESD generated from the cross-over wire between the metal trace of larger line width and the metal trace of smaller line width can be decreased. In addition, in the overlapping region of the second metal layer and the first metal layer, by means of different conductivity of the via hole material, such as metal and ITO conductive film, ESD on the TFT display device can be distributed and led away using capacitance difference between different material. Thus, the TFT display device will have less damage by ESD. The yield rate of the product is increased, and the product competitiveness is enhanced.

In embodiments of the present invention, the first silicon nitride film 23 and the second silicon nitride film 26 can use the same silicon nitride film, such as SiNx film. In other embodiments of the present invention, different silicon nitride films can also be used.

In summary, in the TFT display device of the present invention, a silicon nitride film is deposited on a first metal layer; a second metal layer is deposited on the first silicon nitride film and etched to form a pattern, wherein a second silicon nitride film is deposited on the second metal film; in an overlapping region of the second metal layer and the first metal layer, the first metal layer and/or the second metal layer are disconnected, wherein on the disconnected position, the first silicon nitride layer and the second silicon nitride layer are etched to form the via hole, and an ITO conductive film is deposited to electrically connect the disconnected position. The TFT display device will have less damage by ESD. The yield rate of the product is increased, and the product competitiveness is enhanced.

The above description is only the embodiments of the present invention, and is not used to limit the scope of the present invention. Equivalent structure or equivalent flow chart based on the specification and the drawings of the present invention, or those directly or indirectly applied to other related technology field are all included in the scope of the present invention.

1. A TFT display device, wherein the TFT display device comprises:
a first metal layer, wherein a first silicon nitride film is deposited on the first metal layer;
a second metal layer deposited on the first silicon nitride film and etched to form a pattern, wherein a second silicon nitride film is deposited on the second metal film; and
a via hole, wherein in an overlapping region of the second metal layer and the first metal layer, the first metal layer and/or the second metal layer are disconnected, wherein on the disconnected position, the first silicon nitride layer and the second silicon nitride layer are etched to form the via hole, and an ITO conductive film is deposited to electrically connect the disconnected position;
wherein the via hole is passed through the first silicon nitride film and the second silicon nitride film, and is contacted with the first metal layer and/or the second metal layer, wherein when the first metal layer is disconnected, the ITO conductive film on the via hole position is contacted with the first metal layer, such that the disconnected position of the first metal layer is electrically connected through the ITO conductive film.

2. The TFT display device as claimed in claim 1, wherein the ITO conductive film is coated on the second silicon nitride film.

3. The TFT display device as claimed in claim 1, wherein when the second metal layer is disconnected, the ITO conductive film on the via hole position is contacted with the second metal layer, such that the disconnected position of the second metal layer is electrically connected through the ITO conductive film.

4. A TFT display device, wherein the TFT display device comprises:
a first metal layer, wherein a first silicon nitride film is deposited on the first metal layer;
a second metal layer deposited on the first silicon nitride film and etched to form a pattern, wherein a second silicon nitride film is deposited on the second metal film; and
a via hole, wherein in an overlapping region of the second metal layer and the first metal layer, the first metal layer and/or the second metal layer are disconnected, wherein on the disconnected position, the first silicon nitride layer and the second silicon nitride layer are etched to form the via hole, and an ITO conductive film is deposited to electrically connect the disconnected position.

5. The TFT display device as claimed in claim 4, wherein the via hole is passed through the first silicon nitride film and the second silicon nitride film and is contacted with the first metal layer and/or the second metal layer.

6. The TFT display device as claimed in claim 5, wherein the ITO conductive film is coated on the second silicon nitride film.

7. The TFT display device as claimed in claim 4, wherein when the first metal layer is disconnected, the ITO conductive film on the via hole position is contacted with the first metal layer, such that the disconnected position of the first metal layer is electrically connected through the ITO conductive film.

8. The TFT display device as claimed in claim 4, wherein when the second metal layer is disconnected, the ITO conductive film on the via hole position is contacted with the second metal layer, such that the disconnected position of the second metal layer is electrically connected through the ITO conductive film.

9. A method for producing a TFT display device, wherein the method comprises:
depositing a first silicon nitride film on a first metal layer;
depositing a second metal layer on the first silicon nitride film, etching the second metal layer to form a pattern, and depositing a second silicon nitride film on the second metal layer;
in an overlapping region of the second metal layer and the first metal layer, disconnecting the first metal layer and/or the second metal layer, on the disconnected position, etching the first silicon nitride layer and the second silicon nitride layer to form a via hole, and depositing an ITO conductive film to electrically connect the disconnected position.

10. The method as claimed in claim 9, wherein the via hole is passed through the first silicon nitride film and the second silicon nitride film and is contacted with the first metal layer and/or the second metal layer.

11. The method as claimed in claim 9, wherein the ITO conductive film is coated on the second silicon nitride film.

12. The method as claimed in claim 9, wherein when the first metal layer is disconnected, the ITO conductive film on the via hole position is contacted with the first metal layer, such that the disconnected position of the first metal layer is electrically connected through the ITO conductive film.

13. The method as claimed in claim 9, wherein when the second metal layer is disconnected, the ITO conductive film on the via hole position is contacted with the second metal layer, such that the disconnected position of the second metal layer is electrically connected through the ITO conductive film.
